(19) United States
(12) Patent Application Publication
(10) Pub. No.: US 2002/0149069 A1
(43) Pub. Date: Oct. 17, 2002

(54) Piezoresistive sensor with epi-pocket isolation

(76) Inventors: Janusz Bryzek, Fremont, CA (US); David W. Burns, San Jose, CA (US); Steven S. Nasiri, Saratoga, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/064,295

(22) Filed: Jun. 28, 2002

Related U.S. Application Data
(63) Continuation of application No. 09/141,199, filed on Aug. 27, 1998.

(51) Int. Cl. H01L 29/84; H01L 29/82; H01L 27/14

(52) U.S. Cl. 257/414

(57) ABSTRACT

A semiconductor sensor with epi-pocket isolation is described. In one embodiment, the semiconductor sensor comprises a deformable member which includes a first silicon region of a first conductivity type and a second silicon region of a second conductivity type surrounding the first silicon region. The semiconductor sensor further comprises a stress-sensitive diffused resistive element disposed on the deformable member in the first silicon region.

### CROSS REFERENCE TO RELATED APPLICATIONS

This application is a continuation of application Ser. No. 09/141,199, filed Aug. 27, 1998, abandoned.

### BACKGROUND OF INVENTION

1. Field of the Invention

The present invention relates generally to piezoresistive sensors.

2. Background Information

FIG. 1 illustrates a cross-sectional view of a prior art piezoresistive pressure sensor 2. The piezoresistive sensor 2 consists of a P− substrate and includes a rim region 4 and a thin diaphragm region 6 for mechanically amplifying applied pressure into large bending stresses. A layer of N− silicon 8 is epitaxially deposited on the P− substrate and the diaphragm region 6 to allow for diaphragm formation using electrochemical etching with a p-n junction etch stop. A number of diffused piezoresistors 10 are formed on top of the diaphragm region 6 for converting the large bending stresses into an electrical signal.

FIG. 2 illustrates a diffused piezoresistor 10. The diffused piezoresistor 10 is diffused into the surface of the deformable diaphragm 6. Such piezoresistors are typically P− type for large resistance changes with applied pressure. FIG. 3 illustrates P− type piezoresistors formed in an N− silicon layer or N− substrate where the piezoresistors are connected in a Wheatstone bridge configuration. The N− layer is tied to a high voltage (supply or bridge voltage) to avoid forward biasing the P− N junction between the P− type resistors and the N− layer.

### SUMMARY OF INVENTION

The present invention is a semiconductor piezoresistive sensor with epi-pocket isolation. In one embodiment, the semiconductor sensor comprises a deformable member which includes a first silicon region of a first conductivity type and a second silicon region of a second conductivity type surrounding the first silicon region. The semiconductor sensor further comprises a stress-sensitive diffused resistive element formed on the deformable member in the first silicon region.

The local epi-pocket isolation technique of the present invention provides stability, high performance, and direct compatibility with bi-complementary metal oxide semiconductor (“BICMOS”) processes, particularly when integrated BICMOS electronics.

### BRIEF DESCRIPTION OF DRAWINGS

FIG. 1 is a cross-sectional view of a prior art piezoresistive pressure sensor.

FIG. 2 illustrates a prior art diffused piezoresistor.

FIG. 3 illustrates P− type piezoresistors formed in an N-type epi-layer or N-type substrate, where the piezoresistors are connected in a Wheatstone bridge configuration.

FIG. 4 is a cross-sectional view of a portion of a piezoresistive sensor according to a preferred embodiment of the present invention.

FIG. 5 is a top view of the diffused piezoresistor with epi-pocket isolation according to the embodiment of FIG. 4.

FIG. 6 is a schematic cross section of a diffused piezoresistor in an epi-pocket with a polysilicon shield thereon.

FIG. 7 is a schematic diagram of four diffused piezoresistors formed in local epi-pockets, where the piezoresistors are connected in a Wheatstone bridge configuration.

FIG. 8 is a schematic diagram of four diffused piezoresistors formed in a single epi-pocket, where the piezoresistors are connected in a Wheatstone bridge configuration.

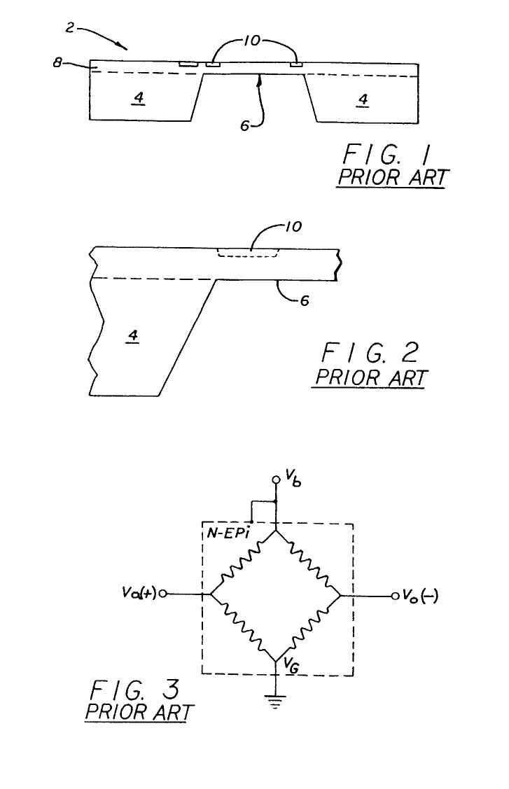

### DETAILED DESCRIPTION

The present invention comprises a semiconductor piezoresistive sensor method and apparatus which includes epi-pocket isolation. In one embodiment, a semiconductor piezoresistive sensor comprises a semiconductor substrate of a first conductivity type having a deformable member. In fabrication, a first layer of the first conductivity type is formed (e.g., implanted) on a first side of the substrate substantially thereacross and a second layer of a second conductivity type is epitaxially deposited on the first layer. The first layer is surrounded by a sinker diffused region of the first conductivity type which forms a pocket proximate to the deformable member. A resistive element is diffused in the second layer within the pocket, where the resistance of the resistive element changes with stress applied to the deformable member.

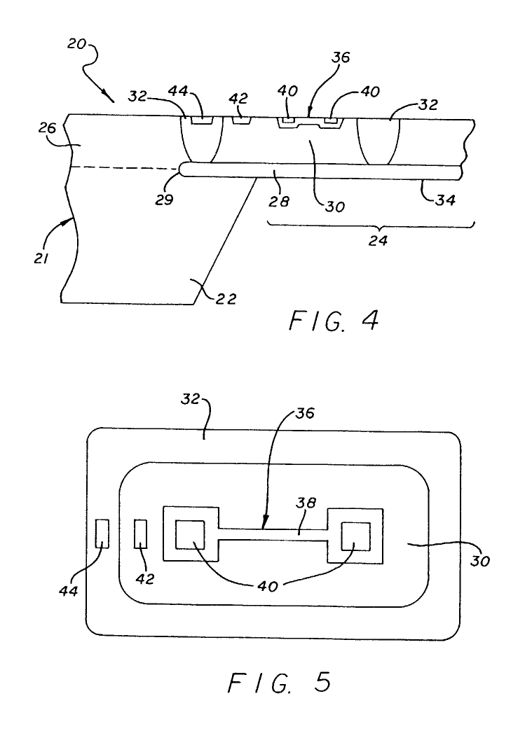

First referring to FIG. 4, a cross-sectional view of a portion of a piezoresistive sensor 20 according to a preferred embodiment of the present invention may be seen. In this embodiment, the piezoresistive sensor 20 is formed by providing a substrate 21 (e.g., P− type), forming a layer 28 (either P− type or N− type) by ion-implantation on top of the substrate 21 extending across the area of the substrate, or at least a portion thereof such as in the region in which a deformable member 24 (e.g., diaphragm) will be formed, and then depositing an N− epitaxial layer 26 (hereinafter referred to as “epi-layer”) on the layer 28. The layer 28 may be locally formed, as shown by numeral 29, prior to depositing the epi-layer 26.

An N− epi-pocket 30 is formed within the epi-layer 26 by surrounding a part of the epi-layer 26 with a P− sinker diffusion region 32. The sinker diffused region 32 extends from the semiconductor surface through the N− epi-layer 26 to the P− buried layer 28, or the substrate which, in the absence of the buried layer, would preferably be a P− substrate. Also shown is a diffused piezoresistor 36 (e.g., P− type) formed in the sub-surface of the epi-pocket 30. Several epi-pockets (e.g., four) may be formed in the deformable member or diaphragm region 24, with each piezoresistor disposed in a separate epi-pocket. In another embodiment, all piezoresistors are disposed in one epi-pocket.

The substrate 21 is then etched from the bottom side (e.g., using a wet etch) up to the buried layer 28, for example, which acts as an etch stop, to form a deformable diaphragm region 24 and a rim region 22. Consequently, the diaphragm region 24 includes the buried layer 28 and the epi-layer 26 formed on top of the buried layer 28. In another embodiment, the substrate 21 may be etched from the bottom-side short of the layer 28 using a dry etch with possibly a buried oxide etch stop, in which case the diaphragm region 24 will include the epi-layer 26, the buried layer 28, and a substrate layer (not shown).

FIG. 5 is a top view of the diffused piezoresistor 36 with epi-pocket isolation according to the embodiment of FIG. 4. Referring to FIGS. 4 and 5, the piezoresistor 36 is comprised of an elongated, diffused region 38, with highly doped P+ contact regions 40 at each end to allow interconnection with the diffused piezoresistor 36. It is important to note that the shape of the piezoresistor 36 may vary. The N− epi-pocket 30 surrounds the piezoresistor 36 and includes a diffused N+ contact region 42 for electrically connecting the epi-pocket 30 to a sufficiently high voltage, such as the highest potential on the chip, the highest bridge voltage, or to the highest local potential of the piezoresistor 36. This provides electrical isolation of the piezoresistor 36 in addition to reducing and controlling voltage sensitivity. The P− sinker diffused region 32 surrounds the epi-pocket 30. A P+ contact region 44 is located in the sinker diffused region 32 for electrically connecting the same to ground.

Epi-pocket isolation involves providing reverse-biased p-n junctions to isolate active device areas from one another. In this particular implementation, epi-pocket isolation effectively separates the precision piezoresistors from other portions of the piezoresistive sensor 20. Junction isolation is achieved by biasing the N− epi-pocket 30 at an electric potential equal to or larger than the voltages at either end of the P− type piezoresistors. A P+ contact region 44 allows the P− sinker diffused region 32 to be placed at a low potential or ground, providing additional electrical isolation and an effective case ground. The local epi-pocket isolation technique of the present invention provides stability, high performance, and direct compatibility with bi-complementary metal-oxide semiconductor (“BICMOS”) processes, particularly when integrated with BICMOS electronics.

Alternatively, the conductivity types of one or more of the substrate 21, buried layer 28, epi-layer 26, sinker diffused region 32, and piezoresistor 36 may be reversed. In the preferred embodiment, P− type piezoresistors are preferred over N-type piezoresistors. It is to be appreciated that the piezoresistive sensor 20 of FIG. 4, which includes a P− buried layer 28, N− epi-layer 26, P− sinker diffused region 32, and a P− type piezoresistor 36, may be formed on an N− substrate 21.

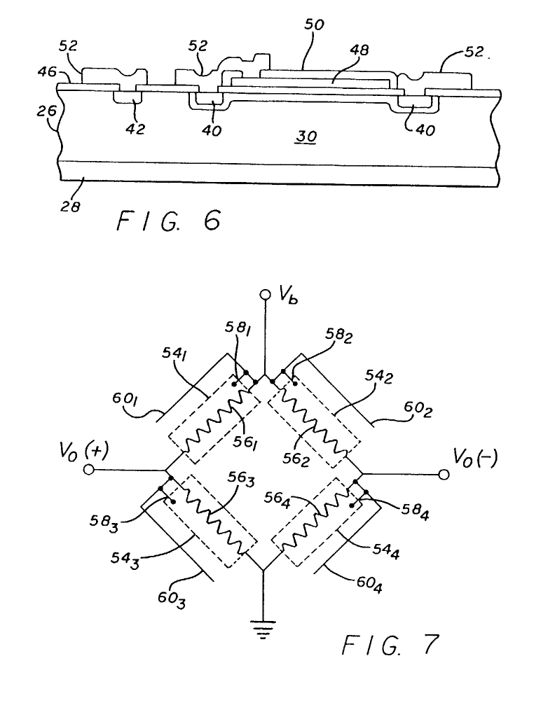

FIG. 6 is a schematic cross section of a diffused piezoresistor in an epi-pocket with a polysilicon shield 48 thereon. After the piezoresistors are formed, an oxide layer 46 is deposited or grown over the epi-layer 26. Then, a conductive layer (e.g., polysilicon) is deposited and patterned to form a polysilicon shield 48 over the oxide layer 46 between the P+ contact regions 40. A second oxide layer 50 is then deposited or grown over the polysilicon shield 48. The oxide layers are masked and etched to expose the N+ contact region 42 and the P+ contact regions 40, and a metallization layer 52 is deposited and patterned to provide certain circuit interconnects. This locally connects the polysilicon shield 48 to a P+ contact region 40 of the piezoresistor 36. Consequently, the polysilicon shield 48 is insulated from the piezoresistor by the oxide layer 46, but locally connected to the same potential as one end of the P− type piezoresistor 36 to provide an electrostatic shield over the piezoresistor.

In another embodiment, the polysilicon shield 48 may be connected to the same potential as the epi-pocket 30 or can be grounded. As the N− epi-pocket 30 provides electrical isolation from the bottom and sides of the piezoresistor sensor 20, the polysilicon shield 48 provides electrical isolation from the top. The shield 48 may alternatively be composed of, for example, metal, CrSi, NiCr or any semiconductor-compatible metal. The polysilicon shield enhances piezoresistor performance by controlling local electric fields, controlling breakdown, and reducing the impact of ionic contamination. In particular, the polysilicon shield provides control of the electrical field distribution in the oxide above the piezoresistor 36, reducing the sensitivity to voltage variations in the biasing circuitry and radiated RFI.

FIG. 7 is a schematic diagram of four diffused piezoresistors 56₁-56₄ formed in local epi-pockets 54₁-54₄, where the piezoresistors are connected in a Wheatstone bridge configuration. As shown, individual epi-pockets 54 are formed for each piezoresistor 56. Each local epi-pocket 54 is tied to the higher voltage potential of the corresponding piezoresistor. More specifically, epi-pockets 54₁ and 54₂ are tied to V_{b} as shown by connections 58₁ and 58₂, respectively, epi-pocket 54₃ is connected to Vo(+) as shown by connection 58₃, and epi-pocket 54₄ is connected to Vo(−) as shown by connection 58₄. This configuration results in minimal voltage sensitivity of bridge output with changes in bridge voltage V_{b}. Also shown are local polysilicon shields 60₁-60₄, which are similarly tied to the higher voltage potential of the corresponding piezoresistors 56₁-56₄. This is a preferred embodiment, as this connection puts field effects of the shield on the piezoresistors, due to variations of the bridge input V_{b}, into the common mode, which is easily rejected by the output electronics. However, in another embodiment, the local polysilicon shields 60₁-60₄ may be tied to the lower impedance ground or bridge connection (V_{b}).

Referring to FIGS. 4 and 7, the P− sinker diffused region 32 and buried layer 28 may be connected to an external ground, allowing junction-isolated separation between the signal ground (bottom of the Wheatstone bridge) and case ground for improved device performance. Grounding the buried layer 28 and/or the diaphragm backside 34 provides electromagnetic interference (“EMI”), radio frequency (“RF”), and reduction of ionic contamination effects.

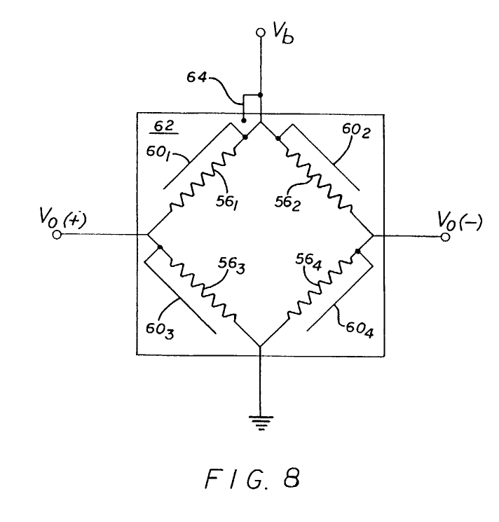

FIG. 8 is a schematic diagram of four diffused piezoresistors formed in a single epi-pocket 62, where the piezoresistors are connected in a Wheatstone bridge configuration. Referring to FIG. 8, the piezoresistors 60₁-60₄ are formed in a single epi-pocket 62, with the epi-pocket being tied to the bridge connection Vb, as shown by connection 64. Also shown are local polysilicon shields 60₁-60₄, which are tied to the higher voltage potential of the corresponding piezoresistors 56₁-56₄. Alternatively, a single polysilicon shield may be placed over the four piezoresistors 601-604 and either tied to the bridge potential or to ground.

The epi-pocket isolation technique of the present invention provides reduced leakage, higher temperature operation, improved stability, and the ability to readily co-fabricate integrated circuits. An epi-pocket surrounding one or more piezoresistors reduces the amount of electrical leakage by minimizing the total surface area surrounding the epi pocket and the periphery at the semiconductor-oxide interface. This implementation also provides reduced leakage by eliminating leakage components at the sides of a sawed off die as in most conventional sensors. Higher temperature operation is obtained as a consequence of the reduced semiconductor leakage paths, and with careful layout of the epi-pockets, the leakage components are common-mode and therefore rejected by the Wheatstone bridge.

Since the piezoresistive element is surrounded by a junction isolated N− epi-pocket, which is driven by a low impedance voltage supply, and the N− epi-pocket is further surrounded by a P− sinker diffused region, which can be held at ground potential, protection against detrimental effects of electromagnetic interference and high electric fields is enhanced. Grounding the sinker diffused region and/or the buried layer is particularly beneficial in the pressure sensor implementation, where electrically conductive fluids may be in direct contact with the back of the silicon die.

The piezoresistors with epi-pocket isolation are selectively fabricated on a silicon die, which is subsequently micro-machined to form stress-enhancing geometries such as pressure sensor diaphragms or accelerometer flexures. The embodiments described herein are compatible with integrated circuit processing, and allow active bipolar and MOS devices to be co-fabricated with the piezoresistor sensor, typically, in a full thickness substrate area, providing a large, buffered output signal with possible on-chip compensation, signal processing, and formatting electronics.

The piezoresistive sensor of the present invention transduces pressure, acceleration, and other physical stimuli into electrical signals suitable for additional analog and digital signal processing in industrial, commercial, automotive, medical, and consumer applications. The present invention may be used in conjunction with, but not limited or restricted to, signal compensation circuitry, conversion and communication electronics, and is generally applicable to fixed-gain operational amplifiers, digital-to-analog and analog-to-digital converters, compactors, and other integrated circuits which benefit from a stable, diffused or implanted resistor.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

1. A semiconductor sensor, comprising:
a diaphragm;
a silicon rim region supporting the bottom surface of the diaphragm;
a first silicon region of a first conductivity type within the diaphragm, the first silicon region having a top surface, an opposing bottom surface, and a peripheral edge that connects the top surface and the bottom surface;
a stress-sensitive first resistive element formed in the diaphragm adjacent the top surface of the first silicon region;
a second silicon region of a second conductivity type surrounding the peripheral edge of the first silicon region; and
a silicon buried layer that is more highly doped than the first silicon region and the second silicon region, the buried layer covering at least a portion of the bottom surface of the first silicon region, contacting the second silicon region, and isolating the first silicon region from the rim region.

2. The semiconductor sensor of claim 1 further comprising second, third, and fourth resistive elements connected to the first resistive element in a Wheatstone bridge configuration, said resistive elements formed on the diaphragm adjacent the top surface of the first silicon region.

3. The semiconductor sensor of claim 2 wherein the diaphragm further includes third, fourth, and fifth silicon regions of the first conductivity type, each surrounded by the second silicon region, wherein the second, third, and fourth resistive elements are formed in the respective third, fourth, and fifth silicon regions.

4. The semiconductor sensor of claim 1 wherein the first conductivity type is an N− semiconductor material and the second conductivity type is a P− semiconductor material.

5. The semiconductor sensor of claim 1 wherein the silicon region of the first conductivity type is connected to a voltage that is higher than or at the same potential as the resistive element potential.

6. The semiconductor sensor of claim 1 wherein the resistive element comprises a P− type resistive element.

7. The semiconductor sensor of claim 1 wherein the second silicon region of the second conductivity type is connected to one of a circuit ground and a case ground.

8. The semiconductor sensor of claim 1 wherein the buried layer is connected to a circuit ground.

9. The semiconductor sensor of claim 1 wherein the second silicon region extends from a surface of the diaphragm through the first silicon region to the buried layer.

10. The semiconductor sensor of claim 1 wherein the rim region is a P− substrate.

11. The semiconductor sensor of claim 1 further comprising a shield electrode disposed above and separated from the resistive element by a dielectric layer.

12. The semiconductor sensor of claim 12 wherein the shield electrode is comprised of any of the following materials: polysilicon, metal, CrSi, or NiCr.

13. The semiconductor sensor of claim 12 wherein the shield is electrically connected to either a local resistor voltage, a supply voltage, or a ground.

14. The semiconductor sensor of claim 1 wherein the diaphragm deflects as a function of pressure applied thereto.

15. The semiconductor sensor of claim 1 wherein the diaphragm deflects as a function of acceleration.

16. A semiconductor diaphragm, comprising:
one or more silicon regions of a first conductivity type, each of the silicon regions having a top surface, an opposing bottom surface, and a peripheral edge that connects the top surface and the bottom surface;
one or more stress-sensitive P− type diffused resistive elements disposed adjacent the top surface of the one or more silicon regions of the first conductivity type;
one or more silicon regions of a second conductivity type, each of the silicon regions of the second conductivity type surrounding the peripheral edge of one of the silicon regions of the first conductivity type and isolating each of the silicon regions of the first conductivity type from adjacent silicon regions of the first conductivity type; and
one or more buried layers that are more highly doped than the silicon regions of the first conductivity type and the silicon regions of the second conductivity type, each buried layer covering the bottom surface of at least one of the silicon regions of the first conductivity type.

17. The semiconductor diaphragm of claim 17 further comprising one or more shield electrodes disposed above and separated from each of the resistive elements by a dielectric layer.

18. The semiconductor diaphragm of claim 18 wherein each of the shields is comprised of one of the following materials: polysilicon, metal, CrSi, or NiCr.

19. The semiconductor diaphragm of claim 18 wherein the shield is electrically connected to either a local resistor voltage, a supply voltage, or a ground.
